(19) United States
(12) Patent Application Publication
(10) Pub. No.: US 2005/0167777 A1
(43) Pub. Date: Aug. 4, 2005

(54) Microelectronic device with active layer bumper

(75) Inventor: Wen-Chin Lee, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/917,196

(22) Filed: Aug. 12, 2004

Related U.S. Application Data
(60) Provisional application No. 60/540,573, filed on Jan. 30, 2004.

(51) Int. Cl. H01L 21/00; H01L 21/8234; H01L 29/94; H01L 31/113

(52) U.S. Cl. 257/510; 438/424; 438/197; 257/288

(57) ABSTRACT

A method comprises providing a substrate having an active layer, forming an isolation trench in the active layer, and forming at least one bumper substantially filling at least one divot formed at an interface between the active layer and the isolation trench during isolation trench formation.

### CROSS-REFERENCE

This application claims the benefit of provisional application “A NOVEL ISOLATION STRUCTURE WITH SEMICONDUCTOR OVER HANG,” Ser. No. 60/540573, filed Jan. 30, 2004, Docket No. 24061.179, naming Wen-Chin Lee as inventor.

### BACKGROUND

An integrated circuit (IC) is formed by creating one or more devices (e.g., circuit components) on a semiconductor substrate using a fabrication process. As fabrication processes and materials improve, semiconductor device geometries have continued to decrease in size from the time such devices were first introduced several decades ago. For example, current fabrication processes are producing devices having feature sizes (e.g., the smallest component (or line) that may be created using the process) of less than 90 nm. However, the continued goal to reduce device geometries may introduce new challenges.

As microelectronic devices are scaled below 45 nm, the increased device leakage current adversely impacts device performance. Microelectronic device performance can further be significantly affected by the defects within layers and/or between features of the device. For example, fissures within insulating features and active device layers can readily cause electrical shorts, parasitic capacitance, and leakage current.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1a-1d are cross-sectional views of one embodiment of a process of forming a semiconductor structure; and

FIG. 2 is a plan view of one embodiment of a microelectronic device.

### DETAILED DESCRIPTION

The present disclosure relates generally to a microelectronic device and method for fabrication, and more specifically to a microelectronic device with active layer bumper. It is understood, however, that the following disclosure provides many different embodiments or examples. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

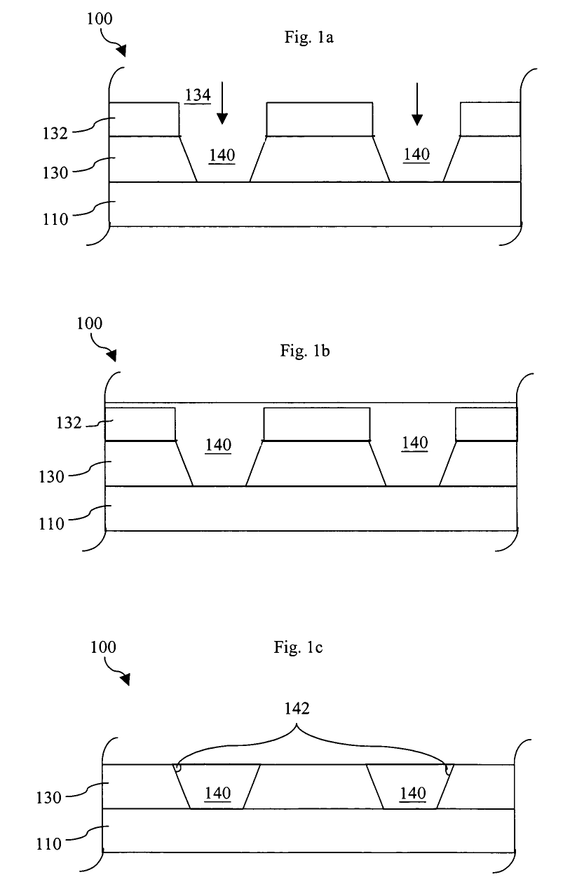

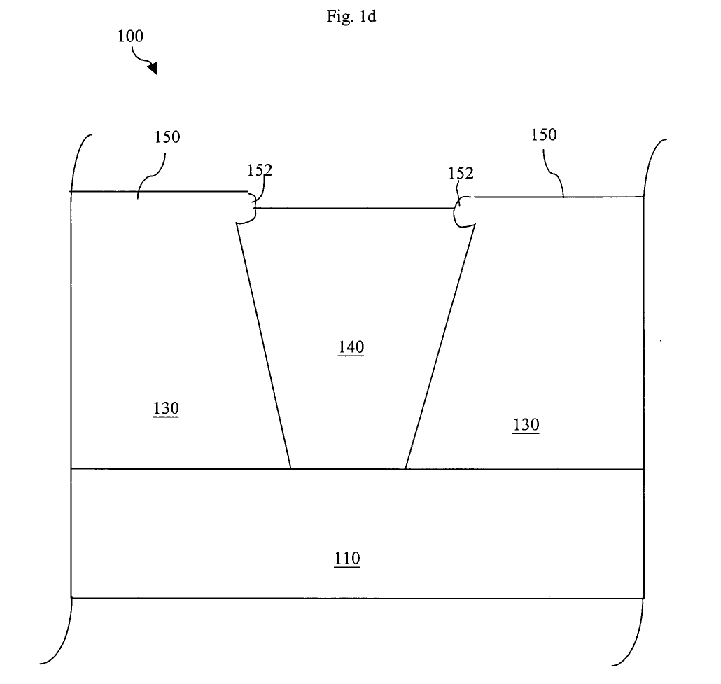

FIGS. 1a-1d are cross-sectional views of one embodiment of a microelectronic device 100. It is understood that FIGS. 1a-1d may include intermediate steps of the manufacture of the microelectronic device 100 not explicitly shown herein.

In FIG. 1a, microelectronic device 100 comprises a structural layer 110 and a mask 132 is used to form a predetermined pattern in an active layer 130.

Structural layer 110 may comprise a plurality of materials suitable for the manufacture of the microelectronic device 100. For example, the structural layer may include silicon (Si), silicon germanium (SiGe), gallium arsenide (GaAs), polymer, diamond, plastic, quartz, sapphire, and/or other materials. Structural layer 110 may also include a material layer such as silicon formed over another layer such as a dielectric layer.

Active layer 130 may include a plurality of microelectronic devices, wherein one or more layers and/or other microelectronic device features may be formed by immersion photolithography, maskless lithography, CVD (chemical vapor deposition), PVD (physical vapor deposition), PECVD (plasma enhanced CVD), ALD (atomic layer deposition), UHVCVD (ultra high vacuum CVD), ALCVD (atomic layer CVD), MOCVD (metal organic CVD), MBE (molecular beam epitaxy), MOVPE (metal organic vapor phase epitaxy), and/or other suitable process techniques. Conventional and/or future-developed lithographic, etching and other processes may be employed to define microelectronic device 100 from the deposited layers(s). Structural layer 110 and active layer 130 may comprise a a silicon substrate, a silicon-on-insulator (SOI) substrate, a polymer-on-silicon, and may comprise silicon, gallium arsenide, gallium nitride, strained silicon, silicon germanium, silicon carbide, carbide, diamond, and/or other materials. Alternatively, structural layer 110 and active layer 130 together may comprise a fully depleted SOI substrate wherein device active layer 130 thickness may range between about 10 Angstroms to about 10,000 Angstroms.

In one embodiment, active layer 130 may be etched to form isolated structures within active layer 130. An etchant 134 may be used with a mask 132 to define areas of active layer 130 to be removed. The formation of a plurality of isolation regions or trenches 140 results. Etchant 134 may be used in a chemical and/or plasma process. For example, a chemical etch may include buffered hydrofluoric acid (HF), and/or other chemicals, while a plasma etch may include reactants including hydrogen bromide (HBr), sulfur hexaflouride (SF₆), nitrogen trifluoride (NF₃), Freon (CF₄), and perfluoride carbons such as C₂F₆, C₃F₈ and/or other reactants. Mask 132 may include polymer photoresist, non-polymer photoresist, an/or other materials for forming trenches 140. Trenches 140 may be shallow trench isolation (STI) structures. Trenches 140 may be formed via one or more etch steps.

Referring to FIG. 1b showing an intermediate processing step, trenches 140 may be filled with a dielectric material, such as silicon dioxide (SiO₂), silicon nitrate (Si₃N₄), and/or other insulating materials. Alternatively, trenches 140 may comprise an air gap. The dielectric material may be formed by CVD, PECVD, PVD, ALD, and/or other process techniques.

In FIG. 1c, the dielectric material over and substantially filling the trenches 140 may be planarized by a plasma and/or chemical etch process. Alternatively, planarization of microelectronic device 100 may be accomplished through chemical mechanical polish and/or chemical mechanical planarization (CMP). The planarization process is then followed by a wet etch process, which removes mask 132 and some of the gap-filling dielectric material. The wet etch process may leave imperfections 142 such as minute depressions or divots along the sidewalls of trench 140 at the interface between trench 140 and active layer 130. Generally, imperfection 142 takes the form of an elongated divot around the active area at the interface between the active region and the shallow trench isolation. Imperfections 142 may be formed due to higher etch rate at higher stress points. These divots often lead to silicide penetration, high junction leakage current, high gate-to-source leakage current, higher source/drain leakage current with corner transistor effects, and other undesirable effects.

Referring to FIG. 1d, a cross-sectional view of one embodiment of microelectronic device 100 is shown. A bumper layer 150 is formed above the active region to fill in the imperfections 142 at the active region-trench interface. As a result of filling in the divots or imperfections, a bumper structure 152 is formed. Bumper layer 150, bumper 152, and/or active region 130 comprises a plurality of conducting and/or semiconductor material which may provide electron and/or hole mobility enhancement and the reduction of leakage current in microelectronic device 100. Bumper layer 150 and bumper 152 may be formed upon and/or within structural layer 110 and/or active layer 130. Bumper layer 150 and bumper 152 may be formed by a suitable selective film deposition process. The selective film deposition process may deposit a facet-free selective film to fill the divot and may be performed before or after the formation of the gate stack. Bumper layer 150 and bumper 152 may be deposited upon active layer 130 by epitaxy, MBE, CVD (UHVCD, ALCVD, MOCVD), PECVD, ALD, PVD, and/or other processes. The deposition process parameters may include a temperature in the range of about 300 to 950 degrees Celsius and pressure greater than 100 mTorr, for example. Forming gases during deposition may contain Si, Ge, H, Cl, N, He, P, B, and As, for example. The filler material forming bumper 152 may comprise Si, strained Si, Ge, SiO₂, SiGe, strained SiGe, diamond, SiC, amorphous Si, Si₃N₄, SiON, metal, metal silicide, and/or other suitable materials. The bumper layer and bumper may also receive an implantation of impurities (for example B, P, As, In, Sb) at a dose greater than 1 E¹⁵ cm⁻².

The location of bumper layer 150, bumper 152, and/or active region 130 may comprise a flat plane over active layer 130, and/or other configurations such as graded, over-hanging, diagonal, and other configurations. Bumper 152 may overhang isolation trench 140 by a distance greater than 10 Angstroms, or a distance that may range between about 10 to about 1000 Angstroms, for example. Bumper layer 150 and/or bumper 152 may have a thickness over 10 Angstroms, or have a thickness of a range between about 2 to about 500 Angstroms, for example. The top surface of the active region may be less than 500 Angstroms higher than the top surface of the isolation trench. Further, the active region may contain stacks of conductive material layers such as metal, metal silicide, Si, Ge, C and/or other suitable materials. For example, the active layer may include a silicon layer, a silicon germanium layer disposed above the silicon layer, and a strained silicon layer disposed above the silicon germanium layer. The active region may also comprise a dopant concentration greater than IE¹⁹ cm⁻³, for example.

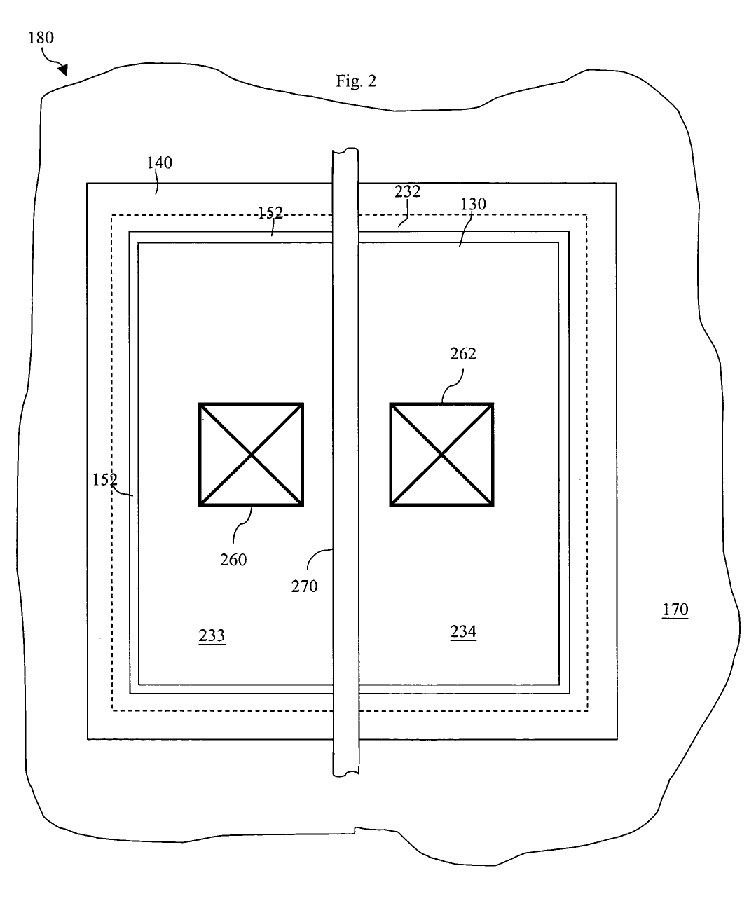

FIG. 2 is a schematic view of another embodiment of microelectronic device 180. Microelectronic device 180 comprises a substrate 170, an active region 130, an isolation trench 140 surrounding the active region, and a bumper 152 disposed at the interface of the trench 140 and active region 130. Device 180 further comprises a doped well 232 substantially enclosing the active region and part of the isolation region, source and drain regions 233 and 234, source and drain contacts 260 and 262, and a gate electrode 270.

Doped well 232 may comprise n-type and/or p-type impurities, and may be formed through ion plantation, diffusion, and/or other impurity insertion methods. Source and drain regions 233 and 234 may also be referred to as “over-drive” (OD) regions, comprising n-type and/or p-type impurities. Source and drain regions 233 and 234 may be configured in a myriad of different geometries and FIG. 2 provides one example of source and drain geometries. Source and drain regions 233 and 234 may be adapted for high voltage operation and/or low voltage operation. Doped well 232 and/or source and drain regions 233 and 234 may be formed by growing a sacrificial oxide on substrate 170, opening a pattern for the location of doped well 232, source and drain regions 233 and 234, and then using a chained-implantation procedure, as is known in the art. It is understood that the substrate 202 may have a P doped well 232 and/or a combination of P and N wells. Doped well 232 and source/drain regions 233 and 234 may comprise boron as a p-type dopant and deuterium-boron complexes for an n-type dopant, for example.

By filling the divots at the interface of the active region and the isolation trenches and forming the bumper structure, undesirable effects such as silicide penetration, high junction leakage current, high gate-to-source leakage current, higher source/drain leakage current with corner transistor effects, etc. are avoided or minimized.

Although embodiments of the present disclosure have been described in detail, those skilled in the art should understand that they may make various changes, substitutions and alterations herein without departing from the spirit and scope of the present disclosure. Accordingly, all such changes, substitutions and alterations are intended to be included within the scope of the present disclosure as defined in the following claims. In the claims, means-plus-function clauses are intended to cover the structures described herein as performing the recited function and not only structural equivalents, but also equivalent structures.

1. A method comprising:
providing a substrate having an active layer;
forming an isolation trench in the active layer; and
forming at least one bumper substantially filling at least one divot formed at an interface between the active layer and the isolation trench during isolation trench formation.

2. The method of claim 1, wherein forming at least one bumper comprises forming at least one bumper overhanging the isolation trench.

3. The method of claim 1, wherein forming at least one bumper comprises forming a bumper layer by selective film deposition.

4. The method of claim 1, wherein forming at least one bumper comprises forming a bumper layer by facet-free selective film deposition.

5. The method of claim 1, wherein forming at least one bumper comprises forming a bumper layer by epitaxy.

6. The method of claim 1, wherein forming at least one bumper comprises forming a bumper layer by a chemical vapor deposition process.

7. The method of claim 1, wherein forming at least one bumper comprises forming a layer having a material selected from the group consisting of a metal, a metal silicide, Si, Ge, and C.

8. The method of claim 1, wherein forming an isolation trench comprises dry etching the active layer.

9. The method of claim 1, wherein forming at least one bumper comprises forming a bumper layer above the active layer whereby a top surface of the bumper layer is less than about 500 Angstroms higher than a top surface of the isolation trench.

10. The method of claim 1, wherein forming at least one bumper comprises forming a bumper that extends over the isolation trench by a distance greater than about 10 Angstroms.

11. The method of claim 1, further comprising forming a gate stack prior to forming the at least one bumper.

12. The method of claim 1, further comprising forming a gate stack after forming the at least one bumper.

13. The method of claim 1, further comprising forming silicide contacts over the active layer.

14. The method of claim 1, further comprising forming implanted impurities in the at least one bumper.

15. The method of claim 14, wherein the implanted impurity is selected from the group consisting of B, P, As, In, and Sb.

16. The method of claim 1, wherein providing an active layer comprises providing an active layer of strained silicon.

17. The method of claim 1, wherein forming the at least one bumper comprises:
forming a bumper layer above the active layer and the isolation trench and filling the at least one divot; and
selectively removing the bumper layer above the isolation trench.

18. The method of claim 1, wherein the active layer comprises:
a silicon layer;
a silicon germanium layer disposed above the silicon layer; and
a strained silicon layer disposed above the silicon germanium layer.

19. A microelectronic device, comprising:
a substrate including an active layer;
an isolation trench extending through the active layer and defining at least one active region;
an elongated divot formed at an interface between the isolation trench and the at least one active region; and
a bumper layer overlying the active region and substantially filling the elongated divot.

20. The microelectronic device of claim 19, wherein the bumper layer substantially filling the elongated divot forms a bumper overhanging the isolation trench.

21. The microelectronic device of claim 19, wherein the bumper layer has a material selected from the group consisting of a metal, a metal silicide, Si, Ge, and C.

22. The microelectronic device of claim 19, wherein a top surface of the bumper layer is less than about 500 Angstroms higher than a top surface of the isolation trench.

23. The microelectronic device of claim 19, wherein the bumper layer substantially filling the elongated divot forms a bumper extending over the isolation trench by a distance greater than about 10 Angstroms.

24. The microelectronic device of claim 19, further comprising a gate stack disposed over the active region.

25. The microelectronic device of claim 19, further comprising at least one silicide contact disposed over the active region.

26. The microelectronic device of claim 19, further comprising implanted impurities in the bumper layer.

27. The microelectronic device of claim 26, wherein the implanted impurity is selected from the group consisting of B, P, As, In, and Sb.

28. The microelectronic device of claim 19, wherein the active region comprises a layer of strained silicon.

29. The microelectronic device of claim 19, wherein the active region comprises:
a silicon layer;
a silicon germanium layer disposed above the silicon layer; and
a strained silicon layer disposed above the silicon germanium layer.

30. The microelectronic device of claim 19, wherein the bumper layer is formed by a selective film deposition process.

31. A device comprising:
a substrate;
an active region defined by an isolation trench;
a divot formed at an interface between the active region and the isolation trench substantially filled with a bumper structure formed via selective film deposition, the bumper structure substantially extending over the isolation trench.
